(19) United States
(12) Patent Application Publication
(10) Pub. No.: US 2002/0175327 A1
(43) Pub. Date: Nov. 28, 2002

(54) Arrangement with a semiconductor component

(76) Inventors: Mareike Katharine Klee, Hueckelhoven (DE); Hans Peter Loebl, Monschau-Imgenbroich (DE)

Correspondence Address: U.S. Philips Corporation, 580 White Plains Road, Tarrytown, NY, 10591, US

(21) Appl. No.: 10/134,186

(22) Filed: Apr. 26, 2002

(30) Foreign Application Priority Data
Apr. 27, 2001 (DE) 10120877.4

(51) Int. Cl. H01L 29/12

(52) U.S. Cl. 257/43

(57) ABSTRACT

The invention relates to an arrangement with a semiconductor component and to a method of manufacturing the arrangement. A control terminal (9) in the semiconductor component is electrically insulated from a substrate (1) by means of a dielectric layer (11). The dielectric layer (11) is formed from aluminum nitride.

The invention relates to the field of semiconductor components in which a control terminal is electrically insulated from a semiconductor substrate by means of a dielectric layer.

Such semiconductor components usually have three terminals denoted the gate (control terminal), the source, and the drain. Single semiconductor components, for example transistors, as well as arrangements with a plurality of semiconductor components are known. These are usually field effect transistors in which the conductivity of the drain-source path is influenced by a control voltage applied between the control terminal and the source, without a control current flowing, i.e. the control takes place without power. The control terminal in present-day semiconductor components of this kind is usually formed from silicon dioxide (SiO₂).

Attempts are made to achieve a high transistor density in the semiconductor components by means of an increasing miniaturization of the transistors. This has the result that a dielectric layer, by means of which the control terminal is electrically insulated from the substrate, has higher capacitance densities. Higher capacitance densities are necessary for achieving a sufficient charge density in view of the small dimensions resulting from the miniaturization. It is provided for this purpose in known semiconductor elements that the dielectric layers of SiO₂ are made thinner. Dielectric layers of approximately 4 nm are used. In the future, dielectric layers with a thickness of approximately 2 to 3 nm are to be used. Such dielectric layers give rise to the problem of increasing tunnel currents.

To counteract this effect in the semiconductor components, oxidic compounds such as ZrO₂, TiO₂, or lanthanum silicates have been proposed. These compounds, however, have the disadvantage that a deposition on silicon may give rise to an SiO₂ intermediate layer between the control terminal and the dielectric layer with a high dielectric constant. The stored charge is considerably reduced thereby.

It is an object of the invention to provide an improved arrangement with a semiconductor component in which a control terminal is electrically insulated from a substrate by means of a dielectric layer, while the dielectric layer has a sufficient dielectric constant for being used in combination with thin control terminals.

According to the invention, this object is achieved in an arrangement as defined in the opening section of claim 1 in that the dielectric layer is formed from aluminum nitride.

An essential advantage over the prior art achieved by the invention is that a dielectric layer is created whose dielectric constant is substantially higher than that of known dielectric layers of SiO₂. Aluminum nitride has a high dielectric constant of approximately ten, whereas SiO₂ has a relative dielectric constant of approximately four.

A further advantage is that the dielectric layer of aluminum nitride is thermodynamically very stable, whereby the formation of SiO₂ intermediate layers is prevented.

High dielectric constants may also be achieved in advantageous further embodiments of the invention in that the dielectric layer is doped with silicon, hydrogen, or oxygen.

Aluminum nitride is provided on the substrate in the manufacture of the arrangement so as to achieve the advantageous arrangement with a semiconductor component. Modem thin-film methods may be used for this, which are known per se, for example sputtering, electron beam evaporation, chemical deposition from the gas phase, molecular beam epitaxy in very thin layers, or methods of depositing atomic or molecular layers. The aluminum nitride is deposited on silicon in these processes.

The invention will be explained in more detail below with reference to an embodiment and a drawing.

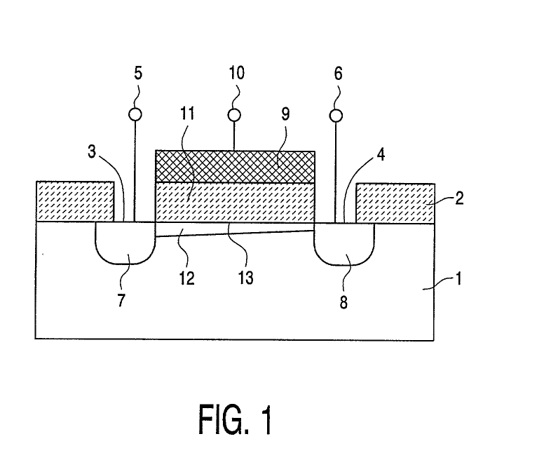

FIG. 1 is a diagrammatic picture of a field effect transistor.

An insulating or dielectric layer 2 of aluminum nitride is provided on a Si substrate 1. A source and a drain connection terminal 5, 6 issue to the exterior in the regions of openings 3, 4 in the insulating layer 2. The source and drain connection terminals 5, 6 are in connection with respective source and drain regions 7, 8.

A gate 9 is connected to a further terminal 10. The gate 9 is insulated from the substrate 1 by means of a portion 11 of the insulating layer 2. An inversion channel 12 is present below the portion 11. The gate is insulated from a surface 13 of the inversion channel 12 by means of the portion 11 of the insulating layer 2.

The use of aluminum nitride as a dielectric layer for insulating the gate region from the substrate may be applied both to MOSFET transistors and to field effect transistors with barrier layers.

The features of the invention disclosed in the above description, the drawing, and the claims may be implemented both singly and in any combination whatsoever for realizing the invention in its carious embodiments.

1. An arrangement with a semiconductor component in which a control terminal (9) is electrically insulated from a substrate (1) by means of a dielectric layer (11), characterized in that the dielectric layer (11) is formed from aluminum nitride.

2. An arrangement as claimed in claim 1, characterized in that the dielectric layer (11) is doped with silicon.

3. An arrangement as claimed in claim 1, characterized in that the dielectric layer (11) is doped with hydrogen.

4. An arrangement as claimed in claim 1, characterized in that the dielectric layer (11) is doped with oxygen.

5. A method of manufacturing an arrangement with a semiconductor component, in which a control terminal (9) is electrically insulated from the substrate (1) by means of a dielectric layer (11) provided on the substrate (1), characterized in that aluminum nitride is provided on the substrate (1) for forming the dielectric layer (11).

6. A method as claimed in claim 5, characterized in that the dielectric layer (11) is doped with silicon.

7. A method as claimed in claim 5, characterized in that the dielectric layer (11) is doped with hydrogen.

8. A method as claimed in claim 5, characterized in that the dielectric layer (11) is doped with oxygen.

9. A method as claimed in any one of the claims 5 to 8, characterized in that the dielectric layer (11) is provided on the substrate by means of one of the following techniques: sputtering, electron beam evaporation, chemical deposition from the gas phase, molecular beam epitaxy, or methods for the deposition of atomic or molecular layers.
